(19) United States
(12) Patent Application Publication
(10) Pub. No.: US 2025/0040376 A1
(43) Pub. Date: Jan. 30, 2025

(54) DISPLAY DEVICE

(71) Applicant: LG Display Co., Ltd., Seoul (KR)

(72) Inventors: KwonHyung LEE, Paju-si (KR); JongHyun PARK, Paju-si (KR); DaeYun HAN, Paju-si (KR)

(73) Assignee: LG Display Co., Ltd., Seoul (KR)

(21) Appl. No.: 18/784,502

(22) Filed: Jul. 25, 2024

(30) Foreign Application Priority Data
Jul. 26, 2023 (KR) 10-2023-0097518

(51) Int. Cl. H10K 59/131

(52) U.S. Cl. CPC H10K 59/131

(57) ABSTRACT

A display device according to an example of the present disclosure includes at least one transparent display panel, a plurality of routing lines disposed on an outside surface of at least one side of the transparent display panel, and a transparent wiring substrate disposed on a rear surface or a top surface of the transparent display panel and having a plurality of connection lines connected to the plurality of routing lines. The connection lines extend to a rear surface of the transparent display panel to overlap a part of the transparent display panel, and a degree of freedom of an attachment position of the transparent display panel can be ensured.

### CROSS-REFERENCE TO RELATED APPLICATIONS

This application claims priority to Korean Patent Application No. 10-2023-0097518 filed on Jul. 26, 2023, in the Korean Intellectual Property Office, the entire contents of which is hereby expressly incorporated by reference into the present application.

### BACKGROUND

### Field

The present disclosure relates to a display device with an improved configuration.

### Discussion of the Related Art

Recently, in accordance with development of various portable electronic devices, such as mobile communication terminals and notebook computers, demands on display devices applicable thereto are increasing.

As the display devices, a liquid crystal display device, a field emission display device, an organic light emitting diode display device, or an inorganic light emitting diode display device is being studied. Among the display devices, an applicable field of an electroluminescent display device including an organic light emitting display device and an inorganic light emitting display device is expanding with advantages of development in mass production technology, ease of driving means, low power consumption, a high image quality, large screen implementation, and flexibility.

The electroluminescent display device includes a plurality of pixels in a matrix and each of the plurality of pixels includes three or more sub pixels and one or more thin film transistors TFT which individually control each sub pixel in the sub pixel.

### SUMMARY OF THE DISCLOSURE

An object to be achieved by various aspects of the present disclosure is to provide a transparent display device with an island shape without forming a dead zone.

Another object to be achieved by various aspects of the present disclosure is to provide a display device which attaches a transparent display panel to a wiring substrate by freely selecting an attachment position of the transparent display panel.

Still another object to be achieved by various aspects of the present disclosure is to provide a display device which attaches a transparent display panel to a wiring substrate by freely selecting an emission direction of the transparent display panel.

Objects of the present disclosure are not limited to the above-mentioned objects, and other objects, which are not mentioned above, can be clearly understood by those skilled in the art from the following descriptions.

According to an aspect of the present disclosure, a display device includes at least one transparent display panel, a plurality of routing lines disposed on an outside surface of at least one side of the display panel, and a transparent wiring substrate which can be disposed on a rear surface or a top surface of the transparent display panel and can have a plurality of connection lines connected to each of the plurality of routing lines, where the plurality of connection lines can extend to a rear surface of the display panel to overlap a part of the display panel.

Other detailed matters of the example embodiments are included in the detailed description and the drawings.

According to the example embodiment of the present disclosure, a wiring substrate and a source printed circuit board to which a signal is led are separately configured and a signal is applied to the display panel through a wiring line on the transparent wiring substrate to manufacture a transparent display device with an island shape without forming a dead zone. Therefore, there is no design restriction due to the dead zone so that a manufacturing cost is reduced. Further, the source printed circuit board, the driving IC, and the like are disposed on an outermost frame of the display device so that the entire transparent display panel can have a uniform transparency.

According to the example embodiment of the present disclosure, the wiring line can be disposed in the overall area of the transparent wiring substrate so that the degree of freedom of the attachment position of the transparent display panel can be ensured.

According to the example embodiment of the present disclosure, the same size is applied to upper and lower substrates of the transparent display panel and side surfaces of the upper and lower substrates are enclosed by a routing line to be in lateral contact with the pad. Therefore, a direction of attaching the display panel to the transparent wiring substrate can be selected to ensure the degree of freedom of the emission direction of the transparent display panel.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram of a display device according to an example embodiment of the present disclosure;

FIG. 2 is a circuit diagram of an example of a sub pixel of the display device of FIG. 1;

FIG. 3 is a perspective view illustrating a display device according to an example embodiment of the present disclosure;

FIG. 4 is a view illustrating an example of an enlarged part of the display device of FIG. 3;

FIG. 5 is a perspective view illustrating placement of a plurality of transparent display panels as an example, in a display device according to an example embodiment of the present disclosure;

FIG. 6 is a view illustrating a cross-section of the display device of FIG. 5;

FIG. 7 is a view illustrating an enlarged part A of FIG. 6;

FIG. 8 is a view illustrating a cross-section of a sub pixel of a display panel of FIG. 6;

FIGS. 9 and 10 are views illustrating a pixel structure as an example of the present disclosure;

FIG. 11 is a perspective view illustrating placement of a plurality of transparent display panels as an example, in a display device according to another example embodiment of the present disclosure;

FIG. 12 is a perspective view illustrating a display device according to still another example embodiment of the present disclosure;

FIGS. 13A and 13B are views illustrating a cross-section of the display device of FIG. 12;

FIG. 14 is a perspective view illustrating a display device according to still another example embodiment of the present disclosure; and

FIGS. 15A and 15B are views illustrating a cross-section of the display device of FIG. 14.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

In construing an element, the element is construed as including an error range although there is no explicit description.

In describing a position relationship, for example, when a position relation between two parts is described as “on,” “over,” “under,” and “next” one or more other parts can be disposed between the two parts unless “just(ly)” or -“direct(ly)” is used.

In describing a time relationship, for example, when the temporal order is described as ‘after^{˜}’, ‘subsequent^{˜}’, ‘next^{˜}’, and ‘before^{˜}’, a case which is not continuous can be included unless “just(ly)” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing the elements of the present disclosure, terms such as first, second, A, B, (a), (b), etc., can be used. Such terms are used for merely discriminating the corresponding elements from other elements and the corresponding elements are not limited in their essence, order, sequence, precedence, or number by the terms. It will be understood that when an element is referred to as being “coupled” or “connected to” another element, it can be directly coupled or directly connected to the other element, or intervening other elements can be present therebetween.

The term “at least one” should be understood as including any and all combinations of one or more of the associated listed elements. For example, the meaning of “at least one of a first element, a second element, and a third element” denotes the combination of all elements proposed from two or more of the first element, the second element, and the third element as well as the first element, the second element, or the third element.

In the present disclosure, examples of a display device can include a narrow-sense display device such as a quantum dot module, an organic light emitting diode (OLED) module or a liquid crystal module (LCM) having a display panel and a driver for driving the display panel. Further, examples of the display device can include a set device (or a set apparatus) or a set electronic apparatus such as a notebook computer, a TV, a computer monitor, an equipment apparatus including an automotive apparatus or another type of apparatus for vehicles, or a mobile electronic device such as a smartphone or an electronic pad, which is a complete product (or a final product) including an LCM, an OLED module, and a quantum dot (QD) module.

Therefore, in the present disclosure, examples of the display device can include a narrow-sense display device itself, such as an LCM, an OLED module, and a QD module, and a set device, which is a final consumer device or an application product including the LCM, the OLED module, and the QD module.

In some embodiments, an LCM, an OLED module, and a QD module including a display panel and a driver can be referred to as a narrow-sense display device, and an electronic device, which is a final product including an LCM, an OLED module, and a QD module can be referred to as a set device. For example, the narrow-sense display device can include a display panel, such an LCM, an OLED module, or a QD module, and a source printed circuit board (PCB), which is a controller for driving the display panel. The set device can further include a set PCB, which is a set controller electrically connected to the source PCB to overall control the set device.

A display panel applied to embodiments of the present disclosure can use any type of display panel, including a liquid crystal display panel, an organic light emitting diode (OLED) display panel, a quantum dot (QD) display panel, and an electroluminescent display panel. The display panel of the embodiment is not limited to a specific display panel capable of bezel bending with a flexible substrate for an organic light emitting diode (OLED) display panel and a lower back plate support structure. Further, a shape or a size of a display panel applied to a display device according to these embodiments is not limited.

In an example where the display panel is the organic light emitting display panel, the display panel can include a plurality of gate lines, data lines, and pixels respectively provided in intersections of the gate lines and the data lines. Further, the display panel can include an array including a thin film transistor (TFT), which is an element for selectively applying a voltage to each of the pixels, a light emitting element layer on the array, and an encapsulation substrate or an encapsulation layer disposed on the array to cover the light emitting element layer. The encapsulation substrate can protect the TFT and the light emitting element layer from an external impact and can prevent water or oxygen from penetrating into the light emitting element layer. Further, a layer provided on the array can include an inorganic light emitting layer, for example, a nano-sized material layer, a quantum dot, or the like.

Features of various embodiments of the present disclosure can be partially or overall coupled to or combined with each other, and can be variously inter-operated with each other and driven technically. Embodiments of the present disclosure can be carried out independently from each other, or can be carried out together in co-dependent relationship. Further, the term “can” encompasses all the meanings and coverages of the term “may.” The term “disclosure” is interchangeably used with, or encompasses all the meanings and coverages of, the term “invention.”

All the components of each display device or apparatus according to all embodiments of the present disclosure are operatively coupled and configured.

Hereinafter, an example embodiment of the present disclosure will be described as below through the accompanying drawings and an example embodiment. The scale of components illustrated in the drawing is not limited to the scale illustrated in the drawing because the scale has a different than an actual scale for the convenience of explanation.

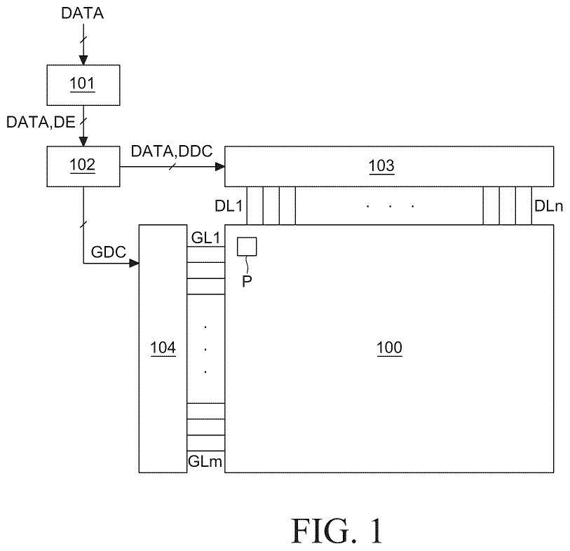

FIG. 1 is a block diagram of a display device according to an example embodiment of the present disclosure.

Referring to FIG. 1, the display device according to an example embodiment of the present disclosure can include an image processor 101, a timing controller 102, a data driver 103, a gate driver 104, and a display panel 100.

For example, the image processor 101 can output a data signal DATA supplied from the outside, a data enable signal DE, and the like. Further, the image processor 101 can output one or more of a vertical synchronization signal, a horizontal synchronization signal, and a clock signal in addition to the data enable signal DE.

The timing controller 102 can be supplied with the data signal DATA together with a driving signal including the data enable signal DE or the vertical synchronization signal, the horizontal synchronization signal, and the clock signal, from the image processor 101. The timing controller 102 can output a gate timing control signal GDC for controlling an operation timing of the gate driver 104 and a data timing control signal DDC for controlling an operation timing of the data driver 103, based on the driving signal.

Further, the data driver 103 samples and latches the data signal DATA supplied from the timing controller 102 in response to the data timing control signal DDC supplied from the timing controller 102 to convert the data signal into a gamma reference voltage and output the converted gamma reference voltage. For example, the data driver 103 can output the data signal DATA through data lines DLI to DLn.

Further, the gate driver 104 can output the gate signal while shifting a level of the gate voltage, in response to the gate timing control signal GDC supplied from the timing controller 102. For example, the gate driver 104 can output the gate signal through gate lines GL1 to GLm.

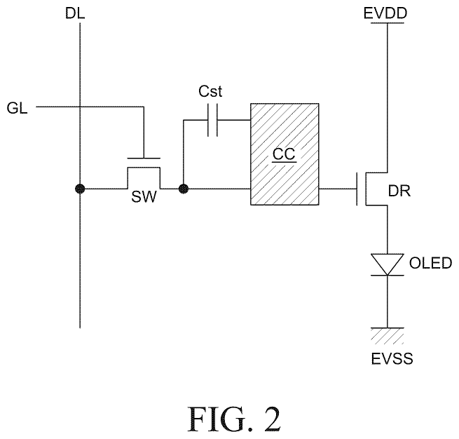

The display panel 100 can display images while a sub pixel P emits light in response to the data signal DATA and the gate signal supplied from the data driver 103 and the gate driver 104. A detailed structure of the sub pixel P will be described in detail with reference to FIGS. 2, 9 to 11.

FIG. 2 is a circuit diagram of a sub pixel of the display device of FIG. 1.

Referring to FIG. 2, one or each sub pixel of the display device according to the example embodiment of the present disclosure can include, for example, a switching transistor SW, a driving transistor DR, a compensation circuit CC, and a light emitting diode OLED.

The light emitting diode OLED can operate to emit light in accordance with a driving current formed by the driving transistor DR.

The switching transistor SW can perform a switching operation such that a data signal supplied through the data line DL is stored in a capacitor Cst as a data voltage in response to a gate signal supplied through the gate line GL.

The driving transistor DR can operate to flow a constant driving current between a high potential power line EVDD and a low potential power line EVSS in response to a data voltage stored in the capacitor Cst.

The compensation circuit CC is a circuit for compensating for a threshold voltage, etc. of the driving transistor DR and can include one or more thin film transistors and capacitors. A configuration of the compensation circuit CC can vary depending on a compensating method.

The sub pixel illustrated in FIG. 2 is configured by a 2T (transistor) 1C (capacitor) structure including a switching transistor SW, a driving transistor DR, a capacitor Cst, and a light emitting diode OLED. When the compensation circuit CC is added, the sub pixel can be configured in various forms, such as 3T1C, 4T2C, 5T2C, 6T1C, 6T2C, 7T1C, and 7T2C, but the example embodiments of the present disclosure are not limited thereto.

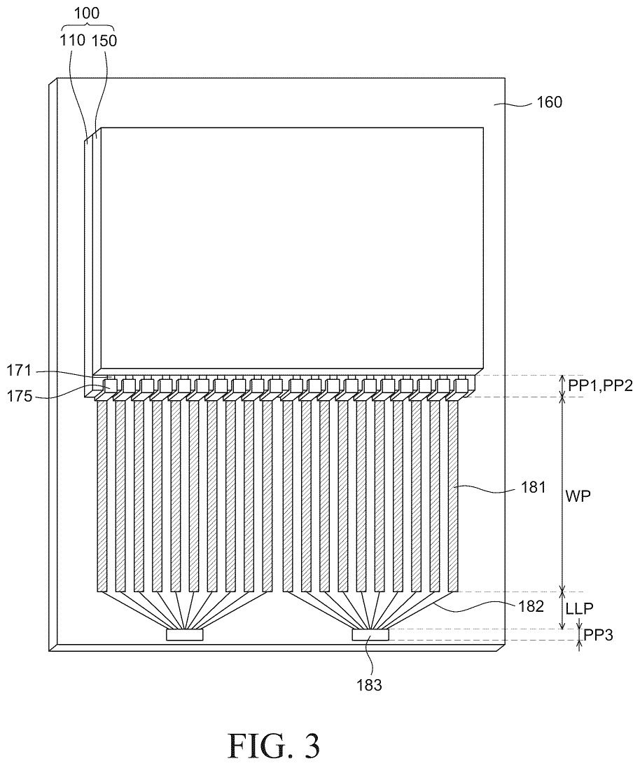

FIG. 3 is a perspective view illustrating a display device according to an example embodiment of the present disclosure.

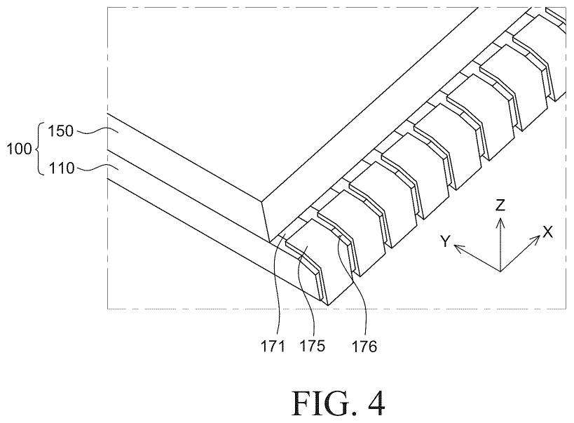

FIG. 4 is a view for enlarging a part of the display device of FIG. 3.

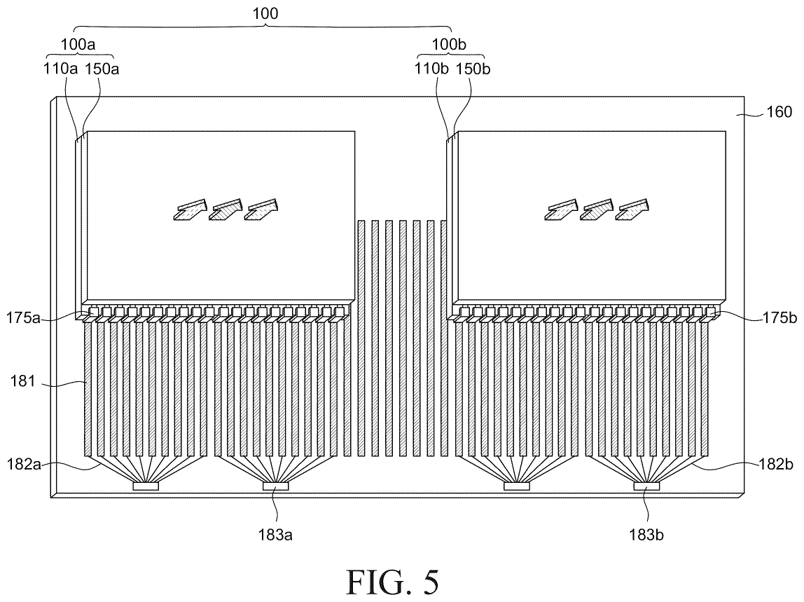

FIG. 5 enlarges a part of a display panel 100.

Referring to FIGS. 3 and 4, the display device according to the example embodiment of the present disclosure can include the display panel 100 and a wiring substrate 160 disposed on a rear surface of the display panel 100. The display panel 100 is a panel for displaying images to a user.

The display panel 100 can include a display element which displays images, a driving element which drives the display element, and wiring lines which transmit various signals to the display element and the driving element. The display element can be defined in different ways depending on a type of the display panel 100. For example, when the display panel 100 is an organic light emitting display panel, the display element can be an organic light emitting diode which includes an anode, an organic layer, and a cathode. As another example, the display element can be a micro LED.

Hereinafter, even though the display panel 100 is assumed as an organic light emitting display panel, the display panel 100 is not limited to the organic light emitting display panel.

The display panel 100 can include an active area and a non-active area. The active area is an area where images are displayed in the display panel 100.

In the active area, a plurality of sub pixels which configures the plurality of pixels and a circuit for driving the plurality of sub pixels can be disposed. The plurality of sub pixels is minimum units which configure the active area, and a display element can be disposed in each of the plurality of sub pixels. The plurality of sub pixels can configure a pixel. For example, an organic light emitting diode which includes an anode, an organic layer, and a cathode can be disposed in each of the plurality of sub pixels, but it is not limited thereto. Further, a circuit for driving the plurality of sub pixels can include a driving element, a wiring line, and the like. For example, the circuit can be configured by a thin film transistor, a storage capacitor, a gate line, a data line, and the like, but is not limited thereto.

The non-active area is an area in which no image is displayed. For example, in the non-active area, various wiring lines and circuits for driving an organic light emitting diode in the active area can be disposed. For example, in the non-active area, a link line or a driving IC for transmitting a signal to a plurality of sub pixels and a circuit in the active area can be disposed, but it is not limited thereto.

Left and right sides of FIG. 3 can be defined as a gate pad part in which a gate driver integrated circuit (IC) is disposed, and a lower side of FIG. 3 can be defined as a data pad part which is connected to a flexible film through a connection line 181, but the present disclosure is not limited thereto. For example, the gate pad part can also be included in the data pad part at the lower side.

At this time, the gate drive IC can be independently formed from the display panel 100 to be electrically connected to the display panel 100 in various methods but can also be configured as a gate in panel (GIP) to be mounted in the display panel 100. In this case, the non-active area can include a GIP area in which a GIP circuit is disposed. For example, the GIP area can be located in the non-active area of the left and right sides of the display panel 100.

The display panel 100 can further include various additional elements to generate various signals or drive the pixel in the active area. The additional elements for driving the pixels can include an inverter circuit, a multiplexer, an electrostatic discharge (ESD) circuit, or the like. The display panel 100 can further include an additional element associated with a function other than a pixel driving function. For example, the display panel 100 can include additional elements which provide a touch sensing function, a user authentication function (for example, fingerprint recognition), a multilevel pressure sensing function, a tactile feedback function, or the like. The additional elements can be located in an external circuit which is connected to the non-active area NA and/or the connecting interface.

For example, the flexible film is disposed on one end of the wiring substrate 160 to supply a power voltage and a data voltage to the plurality of sub pixels and circuits of the active area through the plurality of connection lines 181. For example, the flexible film can be a tape carrier package (TCP) or a chip on film (COF). For example, one edge portion (or an output bonding unit) of the flexible film can be attached to the plurality of third pads (or input pads) 183 disposed on the wiring substrate 160 by a film attachment process using an anisotropic conductive film.

The connection line 181 can be configured by a metal material having low resistance, low reflectance, and high transmittance. For example, the connection lines 181 can be disposed to have a constant pitch. For example, the connection lines 181 are disposed on the entire surface of the wiring substrate 160 with a constant pitch to actively respond to the position change of the display panel 100.

In the meantime, the display panel 100 according to the example embodiment of the present disclosure can include a first substrate 110, a second substrate 150, an element unit, and a routing line 175.

The first substrate 110 can also be represented as a display substrate, a pixel array substrate, a lower substrate, or a base substrate. The first substrate 110 can be formed of a glass material or a plastic material. The first substrate 110 can be a glass substrate, or a thin glass substrate or a plastic substrate which is bendable. For example, the first substrate 110 can be a glass substrate or a tempered glass. For example, the tempered glass can be any one glass of sapphire glass and gorilla glass or a laminated glass thereof.

The display panel 100 can include pixel driving lines and a plurality of pixels disposed on the first substrate 110.

The pixel driving lines are provided on a first surface of the first substrate 110 to supply a signal required to drive each of the plurality of pixels (or emit light). For example, the pixel driving line can include a data line, a gate line, a pixel driving power line (or a first power line), and a pixel common power line (or a second power line). Additionally, the pixel driving line can further include a reference power line (or a sensing line) according to driving (or operation) of a pixel circuit disposed in a circuit area of the pixel.

Each of the pixel driving lines can be electrically connected to a first pad part PP1 disposed in a first edge portion (or a lower side) of the first surface (or a top surface) of the first substrate 110.

The first pad part PP1 can include a plurality of first pads 171 which is disposed side by side along the first direction (e.g., X direction), above an insulating layer which is exposed to the first edge portion of the first surface of the first substrate 110.

For example, the plurality of first pads 171 can be divided (classified) into a plurality of first data pads, a plurality of first pixel driving power pads, and a plurality of first pixel common power pads. Accordingly, the first pad part PP1 can include a first data pad part having a plurality of first data pads connected to a plurality of data lines, a first pixel driving power pad part having a plurality of first pixel driving power pads connected to the plurality of pixel driving power lines, and a first pixel common power pad part having a plurality of first pixel common power pads connected to the plurality of pixel common power lines. Optionally, the first pad part PP1 can further include a first reference power pad part having a plurality of first reference power pads connected to the plurality of reference power lines.

Each of the plurality of pixels can be disposed in each of the plurality of pixel areas disposed with a first interval (or a first pitch) along the first direction (X direction) and the second direction (e.g., Y direction). Each of the plurality of pixels can include a self-emitting element and a pixel circuit. The self-emitting element emits light according to a top emission method based on a signal supplied from corresponding adjacent pixel driving lines to discharge light to an upper portion of the first surface of the first substrate 110. The pixel circuit is connected to adjacent pixel driving lines to allow the self-emitting element to emit light. For example, the pixel circuit can include a driving thin film transistor which supplies a data current corresponding to a data signal supplied through a data line to the self-emitting element.

In the meantime, the first substrate 110 can further include a chamfer 176 formed in a corner portion between the first surface and an outside surface. The chamfer 176 can minimize breakage of the corner portion of the first substrate 110 due to a physical shock from the outside and suppress the disconnection of the routing line 175 according to the corner portion of the first substrate 110. For example, the chamfer 176 has an angle of 45 degrees, but is not necessarily limited thereto. The chamfer 176 can be implemented by a chamfering process using a cutting wheel or a grinding wheel. Therefore, the outside surfaces of the first pads 171 of the first pad part PP1 which is disposed to be in contact with the chamfer 176 are removed or ground by the chamfering process together with the corner portion of the first substrate 110 to include an inclination surface inclined at an angle corresponding to an angle of the chamfer 176.

In the meantime, the first substrate 110 can further include a gate driving circuit (or a gate driver IC) disposed in the active area.

The gate driving circuit can be disposed in the active area to supply a scan signal (or a gate signal) to pixels disposed on the first substrate 110. The gate driving circuit can simultaneously supply a scan signal to the pixels disposed in a horizontal line parallel to the first direction (X direction). For example, the gate driving circuit can supply at least one scan signal to pixels disposed in one horizontal line through at least one gate line.

Further, for example, the gate driving circuit can be implemented by a shift register including a plurality of stage circuit units. For example, the display device according to the present disclosure can include a shift register which is disposed in the active area on the first substrate 110 and supplies the scan signal to the pixels.

Each of the plurality of stage circuit units can include a plurality of branch circuits which is disposed to be spaced apart on each horizontal line of the first substrate 110 along the first direction (X direction). For example, each of the plurality of branch circuits includes at least one thin film transistor (or a branch thin film transistor) and can be disposed one by one between at least one pixel (or a pixel area) in one horizontal line along the first direction (X direction). Each of the plurality of stage circuits generates a scan signal according to a predetermined order in response to a gate control signal supplied through the first pad part PP1 and can supply the scan signal to a corresponding gate line. For example, the gate control signal can include a start signal, a plurality of shift clocks, at least one gate driving power, and at least one gate common power.

For example, the first substrate 110 can further include a gate control line group which is scattered between the plurality of pixels and is connected to the gate driving circuit. Each of the gate control line groups can be selectively connected to the plurality of branch circuits disposed in each of the plurality of stage circuit units. For example, the gate control line group can include a start signal line, a plurality of shift clock lines, at least one gate driving power line, and at least one gate common power line. For example, the plurality of shift clock lines can be divided (or classified) into a plurality of scan clock lines and a plurality of carry clock lines. Here, the plurality of carry clock lines can be omitted.

The first pad part PP1 can further include a first gate pad part having a plurality of first gate pads connected to the gate control line group. For example, the plurality of first gate pads can be divided into a first start signal pad connected to the start signal line, a plurality of first shift clock pads connected to each of the plurality of shift clock lines, at least one first gate driving power pad connected to at least one gate driving power line, and at least one first gate common power pad connected to at least one gate common power line. Accordingly, the first gate pad part can include a first start signal pad, a plurality of first shift clock pads, at least one first gate driving power pad, and at least one first gate common power pad. For example, the plurality of first shift clock pads can be divided (classified) into a plurality of first scan clock pads connected to each of the plurality of scan clock lines and a plurality of first carry clock pads connected to each of the plurality of carry clock lines. Here, the plurality of first carry clock pads can be omitted.

The second substrate 150 can be represented as an encapsulation substrate, an upper substrate, or a cover glass.

The second substrate 150 can be formed of a glass material or a plastic material. The second substrate 150 can be a glass substrate, or a thin glass substrate or a plastic substrate which is bendable. For example, the second substrate 150 can be a glass substrate or a tempered glass. For example, the second substrate 150 can be formed of the same material as the first substrate 110. For example, a size of the second substrate 150 is smaller than a size of the first substrate 110 so that the first substrate 110 can be exposed and the first pad part PP1 can be located on the first surface of the exposed first substrate 110.

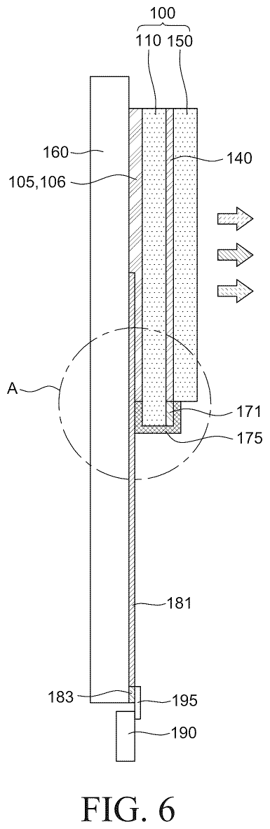

The second substrate 150 can be coupled (or bonded) to the first surface of the first substrate 110 by means of an element unit. The second substrate 150 can include a rear surface (or a back surface) which faces the first surface of the first substrate 110 or is coupled to the element unit, a front surface which is opposite to the rear surface, and an outside surface between the front surface and the rear surface. The element unit can be interposed between the first substrate 110 and the second substrate 150. The element unit will be described in detail below with reference to FIGS. 6 to 8.

The wiring substrate 160 can be disposed on the rear surface of the display panel 100 by means of an adhesive layer. The wiring substrate 160 can be formed of a glass material or a plastic material. The wiring substrate 160 can be a glass substrate, or a thin glass substrate or a plastic substrate which is bendable. For example, the wiring substrate 160 can be a glass substrate or a tempered glass. For example, the wiring substrate 160 can be formed of the same material as the first substrate 110. For example, a size of the wiring substrate 160 can be larger than a size of the display panel 100. The wiring substrate 160 can perform a function of transmitting a signal to the pixel driving lines and increasing a rigidity of the display panel 100. For example, a transmittance of the wiring substrate 160 can be adjusted according to a specification of the display panel 100.

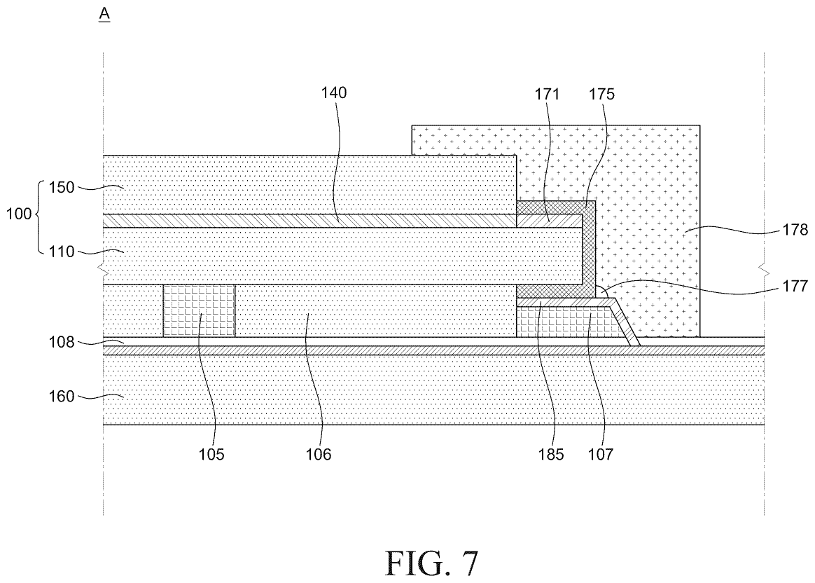

The adhesive layer can be interposed between the display panel 100 and the wiring substrate 160. The adhesive layer will be described in detail below with reference to FIGS. 6 and 7.

For example, the display device according to the example embodiment of the present disclosure can include a second pad part PP2 disposed on the wiring substrate 160. For example, the second pad part PP2 can be disposed on the top surface of the wiring substrate 160 which overlaps the first pad part PP1 disposed on the first substrate 110.

The second pad part PP2 can include a plurality of second pads which is disposed with a constant interval along the first direction (X direction) and overlaps each of the plurality of first pads 171 of the first pad part PP1. For example, the plurality of second pads can be divided (classified) into a plurality of second data pads, a plurality of second pixel driving power pads, and a plurality of second pixel common power pads. Accordingly, the second pad part PP2 can include a second data pad part having a plurality of second data pads, a second gate pad part having a plurality of second gate pads, a second pixel driving power pad part having a plurality of second pixel driving power pads, and a second pixel common power pad part having a plurality of second pixel common power pads. Optionally, the second pad part PP2 can further include a second reference power pad part having a plurality of second reference power pads.

For example, the plurality of second gate pads can be divided (or classified) into a second start signal pad, a plurality of second shift clock pads, at least one second gate driving power pad, and at least one second gate common power pad. Accordingly, the second gate pad part can include a second start signal pad, a plurality of second shift clock pads, at least one second gate driving power pad, and at least one second gate common power pad. For example, the plurality of second shift clock pads can be divided (or classified) into a plurality of second scan clock pads and a plurality of second carry clock pads. Here, the plurality of second carry clock pads can be omitted.

Further, the plurality of routing lines 175 can be disposed so as to enclose an outside surface of the first substrate 110. The routing line 175 according to the example embodiment can be disposed on a first outside surface (or one side surface) among outside surfaces of the first substrate 110. Here, the first outside surface can be an outside surface adjacent to the first edge portion (or a lower side) of the first substrate 110. The routing line 175 can be disposed so as to enclose a first outside surface of the first substrate 110.

For example, each of the plurality of routing lines 175 can be connected to the pixel driving lines disposed on the first substrate 110 one to one (or individually) to be directly connected to the pixel driving lines. As another example, each of the plurality of routing lines 175 can be connected to the pixel driving lines one to one (or individually) through the plurality of pads 171 of the first pad part PP1 disposed on the first substrate 110. In this case, the resistance of the pixel driving lines and/or the voltage drop of a signal applied to the pixel driving lines can be reduced due to the size increase according to the pad 171.

The plurality of routing lines 175 according to the example embodiment can be divided (or classified) into a plurality of data routing lines, a plurality of gate routing lines, a plurality of pixel driving power routing lines, and a plurality of pixel common power routing lines.

Each of the plurality of data routing lines can connect each of the plurality of first data pads disposed in the first pad part PP1 and each of the plurality of second data pads disposed in the second pad part PP2 individually (or one to one).

Each of the plurality of gate routing lines can connect each of the plurality of first gate pads disposed in the first pad part PP1 and each of the plurality of second gate pads disposed in the second pad part PP2 individually (or one to one).

The plurality of gate routing lines according to the example embodiment can be divided (or classified) into a start signal routing line, a plurality of shift clock routing lines, at least one gate driving power routing line, and at least one gate common power routing line. The plurality of shift clock routing lines according to the example embodiment can be divided (or classified) into a plurality of scan clock routing lines and a plurality of carry clock routing lines. Here, the plurality of carry clock routing lines can be omitted.

Further, the start signal routing line can electrically connect a first start signal pad disposed in the first pad part PP1 and a second start signal pad disposed in the second pad part PP2.

Each of the plurality of shift clock routing lines can connect each of the plurality of first shift clock pads disposed in the first pad part PP1 and each of the plurality of second shift clock pads disposed in the second pad part PP2 individually (or one to one).

Each of the plurality of scan clock routing lines, among the plurality of shift clock routing lines according to the example embodiment, can connect each of the plurality of first scan clock pads disposed in the first pad part PP1 and each of the plurality of second scan clock pads disposed in the second pad part PP2 individually (or one to one).

Each of the plurality of carry clock routing lines, among the plurality of shift clock routing lines according to the example embodiment, can connect each of the plurality of first carry clock pads disposed in the first pad part PP1 and each of the plurality of second carry clock pads disposed in the second pad part PP2 individually (or one to one).

Further, at least one gate driving power routing line can electrically connect at least one first gate driving power pad disposed in the first pad part PP1 and at least one second gate driving power pad disposed in the second pad part PP2.

Further, at least one gate common power routing line can electrically connect at least one first gate common power pad disposed in the first pad part PP1 and at least one second gate common power pad disposed in the second pad part PP2.

Each of the plurality of pixel driving power routing lines can connect each of the plurality of first pixel driving power pads disposed in the first pad part PP1 and each of the plurality of second pixel driving power pads disposed in the second pad part PP2 individually (or one to one).

Each of the plurality of pixel common power routing lines can connect each of the plurality of first pixel common power pads disposed in the first pad part PP1 and each of the plurality of second pixel common power pads disposed in the second pad part PP2 individually (or one to one).

Each of the plurality of reference power routing lines can connect each of the plurality of first reference power pads disposed in the first pad part PP1 and each of the plurality of second reference power pads disposed in the second pad part PP2 individually (or one to one).

Further, the display device according to the example embodiment can further include a third pad part (or an input pad part) PP3, a wiring part WP, and a link line part LLP disposed on the wiring substrate 160.

The third pad part PP3 can be disposed at a lower side of the wiring substrate 160. For example, the third pad part PP3 can be disposed in the first edge portion (lower side) of the top surface of the wiring substrate 160. For example, the third pad part PP3 can include a plurality of third pads (or input pads) 183 which is spaced apart from each other to have a predetermined interval.

The wiring part WP can be disposed between the second pad part PP2 and the link line part LLP.

For example, the wiring part WP can include a plurality of connection lines 181 which connects the second pads of the second pad part PP2 and the link lines 182 of the link line part LLP, individually (or one to one).

The link line part LLP can be disposed between the wiring part WP and the third pad part PP3.

For example, the link line part LLP can include a plurality of link lines 182 which connects the connection lines 181 of the wiring part WP and the third pads 183 of the third pad part PP3, individually (or one to one). For example, the plurality of link lines 182 can have a fan shape which extends from the third pad part PP3 toward the wiring part WP.

The display device according to the example embodiment of the present disclosure can further include a driving circuit unit.

The driving circuit unit drives pixels disposed on the first substrate 110 (or emits light) based on digital image data supplied from a display driving system and a synchronization signal to display an image corresponding to image data in the active area. The driving circuit unit is connected to the third pad part PP3 disposed in the first edge portion of the wiring substrate 160 and can output a data signal which drives the pixel disposed on the first substrate 110 (or emits light), and a gate control signal and a driving power to the third pad part PP3. For example, the driving circuit unit is disposed at the outside of the wiring substrate 160 so that a transparent display device with an island shape can be provided without forming a dead zone in the display device.

For example, when a transparent display panel is simply attached onto a mounting glass plate, a bonding area of a driving integrated circuit IC, a printed circuit board, and the like is present inside the glass plate, which can cause a dead zone which is visually opaque. Further, there can be a restriction in the design due to the fixed position of the display panel and the dead zone. Therefore, according to the example embodiment of the present disclosure, the wiring substrate 160 to which the signal is led, and the printed circuit board are separately configured and the signal is applied to the display panel 100 through the connection line 181 on the wiring substrate 160. Accordingly, the transparent display device having an island shape can be manufactured without forming an opaque dead zone. Therefore, there is no design restriction due to the dead zone so that a manufacturing cost is reduced. Further, the source printed circuit board and the driving IC can be disposed on an outermost frame of the display device so that the entire transparent display panel 100 can have a uniform transparency. For reference, the transparent display device is a display device equipped with a transparent or translucent surface and this display device can provide a function which allows a user to check the background while watching contents displayed on the transparent display panel 100. The transparent display device can be utilized in various fields and for example, can be used for a smart device, a window, an exhibition hall, or an advertisement display, and a new industry and an application field can be extended in accordance with a future technological development.

According to the example embodiment of the present disclosure, a pitch of the connection line 181 on the wiring substrate 160 is set to be constant and the connection line 181 is formed on the entire area of the wiring substrate 160 to ensure a degree of freedom of the attachment position of the transparent display panel 100. This will be described in more detail with reference to FIGS. 5 to 7.

FIG. 5 is a perspective view illustrating placement of a plurality of transparent display panels as an example, in a display device according to an example embodiment of the present disclosure.

FIG. 6 is a view illustrating a cross-section of the display device of FIG. 5.

FIG. 7 is a view enlarging a part A of FIG. 6.

Particularly, FIG. 5 illustrates an example that two display panels 100a and 100b are horizontally disposed on one wiring substrate 160, but it is not limited thereto.

FIG. 6 illustrates a part of a cross-section taken along one connection line 181 of the display device of FIG. 5 as an example. Even though in FIG. 6, a cross-section of a first display panel 100a or a second display panel 100b is illustrated, for the convenience of description, the first display panel 100a and the second display panel 100b are referred to as a display panel 100.

Referring to FIGS. 5 to 7, the display device according to the example embodiment of the present disclosure can include, for example, two display panels (100a, 100b: 100) and one wiring substrate 160 disposed on rear surfaces of the display panels (100a, 100b: 100). However, the present disclosure is not limited to the number of display panels (100a, 100b: 100) and the wiring substrates 160.

For example, the display panels (100a, 100b: 100) can include a first display panel 100a and a second display panel 100b which are sequentially disposed in a horizontal direction. The first display panel 100a and the second display panel 100b can have the same size or different sizes. The first display panel 100a and the second display panel 100b can be disposed at the same height or at different heights. Up, down, left, and right attachment positions of the first display panel 100a and the second display panel 100b can be freely changed. A formation position of link lines 182a and 182b and third pads 183a and 183b corresponding (belonging) to the first display panel 100a and the second display panel 100b can be changed according to the selected attachment position.

As described above, the connection line 181 is disposed on the entire surface of the wiring substrate 160 with a predetermined pitch so that there can be a margin so as to respond to the position change of the first display panel 100a and the second display panel 100b.

For example, the left-right position of the first display panel 100a and the second display panel 100b can be adjusted to set an integer multiple of the pitch of the connection line 181 of the wiring substrate 160 and the attachment position of the flexible film 195 can also be adjusted together.

The display panel 100 is a panel for displaying images to a user.

The lower side of FIG. 5 can be defined as a data pad part which is connected to the flexible film 195 through the connection line 181, but it is not limited thereto. For example, the gate pad part can also be included in the data pad part at the lower side.

The flexible film 195 is a film which supplies a signal to the plurality of sub pixels and the circuits of the active area and can be electrically connected to the wiring substrate 160. The flexible film 195 is disposed on one end of the wiring substrate 160 to supply a power voltage and a data voltage to the plurality of sub pixels and circuits of the active area through the plurality of connection lines 181. For example, a driving IC such as a data driver IC can be disposed on the flexible film 195.

The connection line 181 can be configured by a metal material having low resistance, low reflectance, and high transmittance. According to the example embodiment of the present disclosure, the connection line 181 can extend to a rear surface of the display panel 100 so as to overlap a part of the display panel 100.

An insulating layer 108 can be disposed on the connection line 181. The insulating layer 108 can be disposed to insulate the connection line 181 from configurations above the connection line 181 and for example, can be configured by a signal layer or a multiple layer of silicon oxide (SiOx) or silicon nitride (SiNx).

The flexible film 195 can be a tape carrier package (TCP) or a chip on film (COF). At this time, for example, one edge portion (or an output bonding unit) of the flexible film 195 can be attached to the plurality of third pads (or input pads) 183 disposed on the wiring substrate 160 by a film attachment process using an anisotropic conductive film. Further, the other edge portion (or an input bonding unit) of the flexible film 195 can be attached to the printed circuit board 190 by a film attachment process using an anisotropic conductive film.

The printed circuit board 190 is disposed on one end of the flexible film 195 to be connected to the flexible film 195. The printed circuit board 190 is a component which supplies signals to the driving IC. For example, the printed circuit board 190 can supply various signals such as a driving signal or a data signal to the driving IC.

As described above, each of the display panels (100a, 100b: 100) according to the example embodiment of the present disclosure can include a first substrate (110a, 110b: 110), a second substrate (150a, 150b: 150), an element unit 140, and routing lines (175a, 175b: 175).

For example, for example, the first display panel 100a can include a first-first substrate 110a, a first second substrate 150a, an element unit 140, and a first routing line 175a and the second display panel 100b can include a second first substrate 110b, a second-second substrate 150b, an element unit 140, and a second routing line 175b.

As described above, when the first substrate 110 is referred below for the convenience of description, the first-first substrate 110a and the second first substrate 110b are included and when the second substrate 150 is referred, the first second substrate 150a and the second-second substrate 150b are included. When the display panel 100 is referred, the first display panel 100a and the second display panel 100b are included.

The first substrate 110 can also be represented as a display substrate, a pixel array substrate, a lower substrate, or a base substrate.

Each display panel 100 can include pixel driving lines and a plurality of pixels disposed on the first substrate 110.

Each of the pixel driving lines can be electrically connected to a plurality of first pads 171 disposed in a first edge portion (or a lower side) of the first surface (or a top surface) of the first substrate 110.

For example, the plurality of first pads 171 can be divided (classified) into a plurality of first data pads, a plurality of first pixel driving power pads, and a plurality of first pixel common power pads.

The second substrate 150 can be represented as an encapsulation substrate, an upper substrate, or a cover glass. For example, the second substrate 150 can be formed of the same material as the first substrate 110. For example, a size of the second substrate 150 is smaller than a size of the first substrate 110 to expose the first substrate 110 and the plurality of first pads 171 can be located on the first surface of the exposed first substrate 110.

The second substrate 150 can be coupled (or bonded) to the first surface of the first substrate 110 by means of an element unit 140. The second substrate 150 can include a rear surface (or a back surface) which faces the first surface of the first substrate 110 or is coupled to the element unit 140, a front surface which is opposite to the rear surface, and an outside surface between the front surface and the rear surface.

The element unit 140 can be interposed between the first substrate 110 and the second substrate 150. For example, the element unit 140 can be configured by a TFT element layer including a thin film transistor, a light emitting diode layer including a light emitting diode, and an encapsulation layer including an adhesive film, but it is not limited thereto. The first substrate 110 and the second substrate 150 can be bonded to be opposite to each other by means of the element unit 140. For example, for example, the first surface of the first substrate 110 can be coupled to one surface of the element unit 140 and the rear surface of the second substrate 150 can be coupled to the other surface of the element unit 140. Therefore, the first substrate 110 and the second substrate 150 which are bonded (or coupled) to each other by means of the element unit 140 can configure the display panel 100.

In the meantime, the wiring substrate 160 can be disposed on the rear surface of the display panel 100 by means of an adhesive layer 106. The wiring substrate 160 can be formed of a glass material or a plastic material. The wiring substrate 160 can be a glass substrate, or a thin glass substrate or a plastic substrate which is bendable. For example, the wiring substrate 160 can be a glass substrate or a tempered glass. For example, the wiring substrate 160 can be formed of the same material as the first substrate 110. For example, a size of the wiring substrate 160 can be larger than a size of the display panel 100. The wiring substrate 160 can perform a function of transmitting a signal to the pixel driving lines and increasing a rigidity of the display panel 100.

The adhesive layer 106 can be interposed between the display panel 100 and the wiring substrate 160. The display panel 100 and the wiring substrate 160 can be bonded to be opposite to each other by means of the adhesive layer 106. For example, the second surface (or the rear surface) of the first substrate 110 of the display panel 100 can be coupled to one surface of the adhesive layer 106 and the top surface of the wiring substrate 160 can be coupled to the other surface of the adhesive layer 106. Accordingly, the display panel 100 and the wiring substrate 160 which are bonded (or coupled) to each other by means of the adhesive layer 106 can configure a transparent display device having an island shape.

For example, the display device according to the example embodiment can include a second pad part PP2 (see FIG. 3) disposed on the wiring substrate 160. For example, the second pad part PP2 can be disposed on the top surface of the wiring substrate 160 which overlaps the first pad part PP1 (see FIG. 3) disposed on the first substrate 110.

The second pad part PP2 can include a plurality of second pads 185 which is disposed with a constant interval along the first direction (X direction, see FIG. 3) and overlaps each of the plurality of first pads 171 of the first pad part PP1. For example, the plurality of second pads 185 can be divided (classified) into a plurality of second data pads, a plurality of second pixel driving power pads, and a plurality of second pixel common power pads.

For example, the second pad 185 can apply a double film of Ti/Cu which is applicable to a laser soldering process, but is not limited thereto.

The plurality of routing lines 175 is disposed on a lower side of the display panel 100 so as to enclose an outside surface of the first substrate 110 so that a step supplement layer 107 which considers the step can be disposed. For example, the step supplement layer 107 can be configured by an organic insulating layer of photo acryl (PAC), but is not limited thereto.

Therefore, the plurality of second pads 185 is disposed on a top surface of the step supplement layer 107 and extends along an inclined side surface of the step supplement layer 107 to be electrically connected to the connection line 181 therebelow. For example, the second pad 185 can be electrically connected to the connection line 181 through a contact hole formed in the insulating layer 108.

In the meantime, the display device according to the example embodiment of the present disclosure can further include a support layer 105 which is disposed between the display panel 100 and the wiring substrate 160 to maintain a constant gap between the display panel 100 and the wiring substrate 160. For example, the support layer 105 can be dispersed in the adhesive layer 106. The support layer 105 can be a column spacer. For example, the support layer 105 can be configured by an organic insulating layer of photo acryl (PAC), but is not limited thereto.

For example, after attaching two display panels of the first display panel 100a and the second display panel 100b to the wiring substrate 160, in order to reinforce the connection of the routing lines (175a, 175b: 175) and the second pad 185, a solder paste 177 can further be applied between the side surfaces of the routing lines (175a, 175b: 175) and the top surface of the second pad 185.

For example, after dotting the solder paste 177, reflow can be performed with an IR continuous wave (CW) laser of a wavelength of approximately 1064 mm.

Further, for example, a sealant 178 can be applied so as to cover the routing lines (175a, 175b: 175), the second pad 185, a part of the top surface of the wiring substrate 160, and a part of the lower side of the display panel 100, including the solder paste 177. For example, the sealant 178 can be formed of a transparent organic material.

In the meantime, a structure of a sub pixel of a display panel in the display device according to the example embodiment of the present disclosure configured as described above will be described in detail with reference to the drawing.

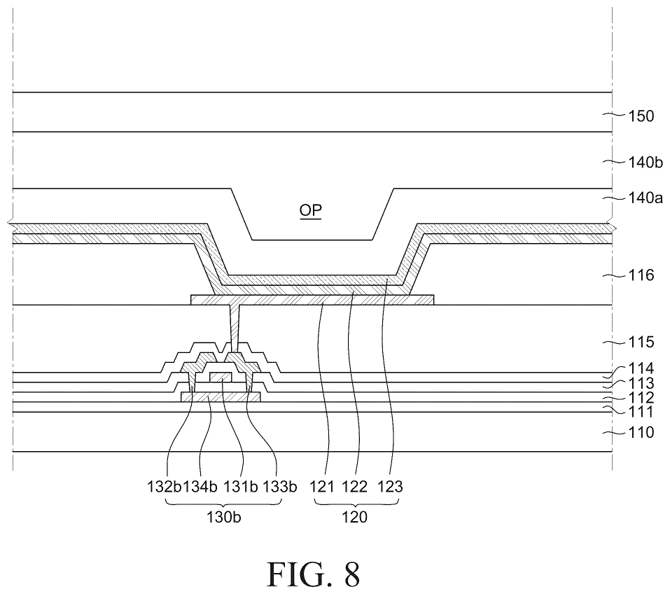

FIG. 8 is a view illustrating a cross-section of a sub pixel of a display panel of FIG. 6. For the convenience of description, in FIG. 8, a driving transistor 130b (DR of FIG. 2 described above) among the plurality of transistors and capacitors of the sub pixel are illustrated.

Referring to FIG. 8, the first substrate 110 is a support member for supporting other components of the display device and can be configured by an insulating material.

The first substrate 110 can be divided into an active area and a non-active area.

In the active area of the first substrate 110, a driving transistor 130b, a light emitting diode 120, and an adhesive film 140b can be disposed. The adhesive film 140b can configure an encapsulation layer.

A buffer layer 111 can be disposed above the first substrate 110. The driving transistor 130b can be disposed above the buffer layer 111.

A switching transistor can be disposed above the buffer layer 111. Other sensing transistor, compensation circuit, and the like can also be provided on the display panel.

The switching transistor can include a first gate electrode, a first source electrode, a first drain electrode, and a first semiconductor layer.

The driving transistor 130b can include a second gate electrode 131b, a second source electrode 132b, a second drain electrode 133b, and a second semiconductor layer 134b.

A gate insulating layer 112 can be disposed on the second semiconductor layer 134b of the driving transistor 130b.

The second gate electrode 131b can be disposed on the gate insulating layer 112.

An interlayer insulating layer 113 can be disposed between the second gate electrode 131b and the second source electrode 132b and the second drain electrode 133b.

The second source electrode 132b and the second drain electrode 133b can be disposed above the interlayer insulating layer 113.

A protection layer 114 can be disposed on the driving transistor 130b. A planarization layer 115 can be disposed on the protection layer 114.

The plurality of light emitting diodes 120 can be disposed in the plurality of sub pixels on the planarization layer 115. The light emitting diode 120 can include an anode 121, an organic layer 122, and a cathode 123.

The organic layer 122 can be disposed between the anode 121 and the cathode 123. The organic layer 122 is an area where light is emitted by the coupling of the electrons and holes supplied from the anode 121 and the cathode 123.

A bank 116 can be disposed on the anode 121 and the planarization layer 115.

The organic layer 122 can be disposed on the anode 121 and the bank 116. The cathode 123 can be disposed on the organic layer 122.

The protection layer 140a can be disposed above the first substrate 110 on which the cathode 123 is disposed.

The adhesive film 140b and the second substrate 150 can be sequentially disposed on the protection layer 140a. However, the display device according to the example embodiment of the present disclosure is not limited to this laminated structure.

The second substrate 150 can be disposed on the adhesive film 140b. The second substrate 150 can protect the light emitting diode 120 of the pixel unit together with the adhesive film 140b.

Hereinafter, a transparent pixel structure for implementing a transparent display panel and a transparent display device according to an example of the present disclosure will be described in detail with reference to the drawings.

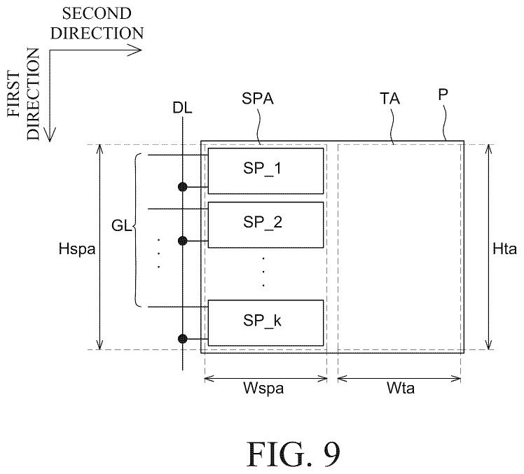

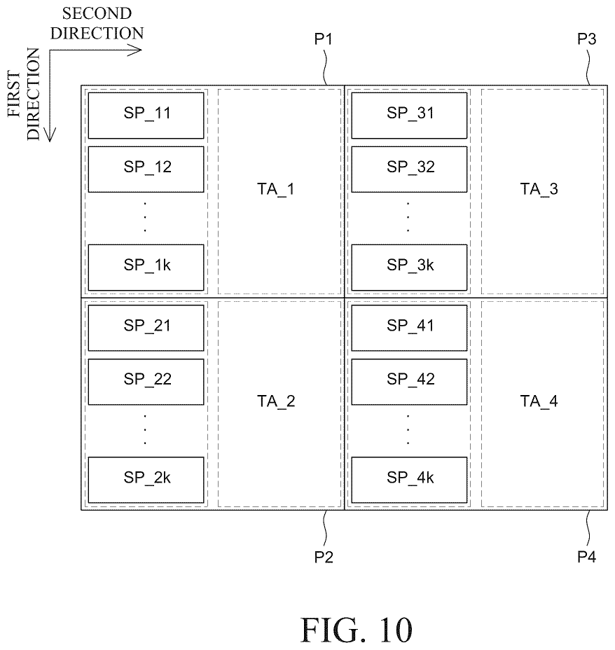

FIGS. 9 and 10 are views illustrating a pixel structure as an example. Particularly, FIGS. 9 and 10 illustrate a transparent pixel structure of a transparent display device according to an embodiment as an example. Further, FIG. 9 illustrates a transparent pixel structure of one transparent pixel and FIG. 10 illustrates four transparent pixels as an example.

Referring to FIG. 9, one transparent pixel can be configured by a sub pixel area SPA in which k sub pixels SP_1, SP_2, . . . , SP_k expressing different colors are formed and a transparent area TA.

Here, k means the number of sub pixels included in one transparent pixel can be 3 or 4 and, in some cases, can be a natural number of 2 or 5 or larger.

In one transparent pixel, the sub pixels SP_1, SP_2, . . . , SP_k can be disposed to be adjacent to each other in the first direction.

The transparent area TA can be disposed to be adjacent to the sub pixel area SPA in the second direction. For example, the transparent area TA can be disposed to be adjacent to the sub pixels SP_1, SP_2, . . . , SP_k in the second direction.

As described above, each transparent pixel includes the transparent area TA so that the transparent pixel has a transparent structure. The transparent display panel and the transparent display device according to the example embodiment can be implemented by the transparent pixel structure.

For example, in each transparent pixel, a height Hta of the transparent area TA can correspond or be similar to a height Hspa of the sub pixel area SPA and a width Wta of the transparent area TA can be narrower than, equal to, or larger than a width Wspa of the sub pixel area SPA. Here, a ratio (Ata/Aspa) between a size (Ata=Wta×Hta) of the transparent area TA determined by the width W and the height H and a size (Aspa=Wspa×Hspa) of the sub pixel area SPA can be determined by at least one of a transmittance and a resolution of the transparent display device.

At this time, as the size Ata of the transparent area TA is larger than the size Aspa of the sub pixel area SPA, for example, as the ratio (Ata/Aspa) between size (Ata=Wta×Hta) of the transparent area TA and the size (Aspa=Wspa×Hspa) of the sub pixel area SPA is increased, the transparency of the transparent pixel can be increased and the transparency of the transparent display device can be increased.

FIG. 10 is a view illustrating four transparent pixels P1, P2, P3, and P4 having the transparent pixel structure of FIG. 9. A first transparent pixel P1 and a second transparent pixel P2 can be disposed to be adjacent in the first direction and a third transparent pixel P3 and a fourth transparent pixel P4 can also be disposed to be adjacent in the first direction. The first transparent pixel P1 and the third transparent pixel P3 can be disposed to be adjacent in the second direction and the second transparent pixel P2 and the fourth transparent pixel P4 can also be disposed to be adjacent in the second direction.

Referring to FIG. 10, the first transparent pixel P1 can be configured by k first sub pixels SP_11, P_12, . . . , SP_1k which are formed in the sub pixel area SPA and are adjacent to each other in the first direction and a first transparent area TA_1 which is disposed to be adjacent to the sub pixel area SPA in the second direction.

The second transparent pixel P2 can be configured by k second sub pixels SP_21, P_22, . . . , SP_2k which are formed in the sub pixel area SPA and are adjacent to each other in the first direction and a second transparent area TA_2 which is disposed to be adjacent to the sub pixel area SPA in the second direction.

The third transparent pixel P3 can be configured by k third sub pixels SP_31, P_32, . . . , SP_3k which are formed in the sub pixel area SPA and are adjacent to each other in the first direction and a third transparent area TA_3 which is disposed to be adjacent to the sub pixel area SPA in the second direction.

The fourth transparent pixel P4 can be configured by k fourth sub pixels SP_41, P_42, . . . , SP_4k which are formed in the sub pixel area SPA and are adjacent to each other in the first direction and a fourth transparent area TA_4 which is disposed to be adjacent to the sub pixel area SPA in the second direction.

The transparent areas TA_1 and TA_2 of the first transparent pixel P1 and the second transparent pixel P2 adjacent in the first direction can be disposed to be adjacent to each other. Further, the transparent areas TA_3 and TA_4 of the third transparent pixel P3 and the fourth transparent pixel P4 adjacent in the first direction can be disposed to be adjacent to each other.

In the meantime, according to another example embodiment of the present disclosure, the plurality of display panels can be disposed on the wiring substrate not only in a left and right direction, but also in an up and down direction, and this will be described in detail with reference to the drawing.

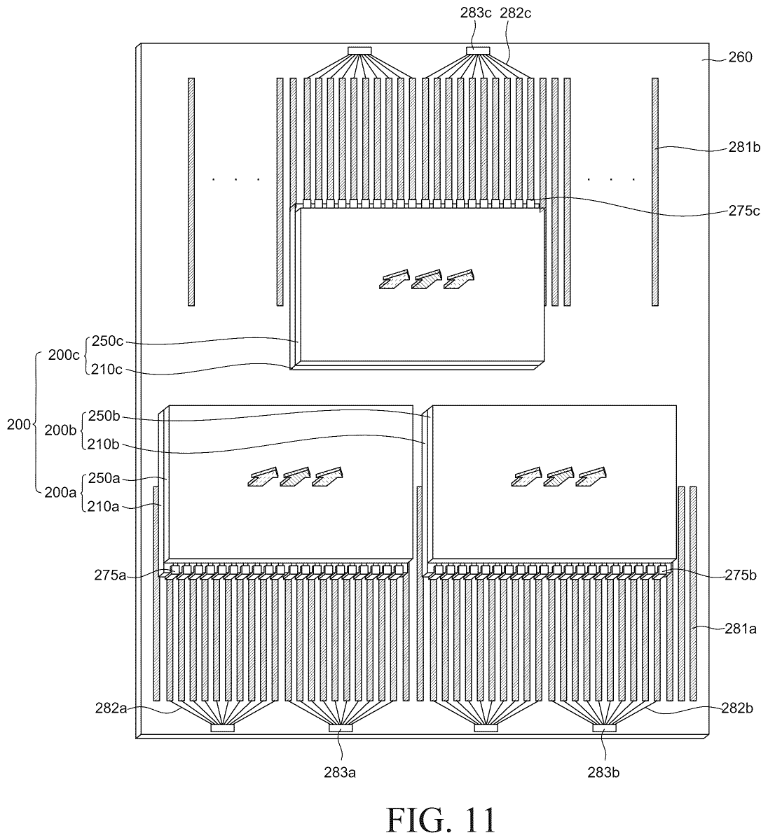

FIG. 11 is a perspective view illustrating placement of a plurality of transparent display panels as an example, in a display device according to another example embodiment of the present disclosure.

A display device according to another example embodiment of the present disclosure of FIG. 11 is formed by the substantially same configuration as the display device of the example embodiment of FIGS. 5 to 7 described above except that a plurality of display panels (200a, 200b, 200c: 200) is disposed on a wiring substrate 260 not only in the left and right direction, but also in the up and down direction. Therefore, the same configuration is denoted by the same reference numeral and a description thereof will be omitted or may be briefly provided.

Particularly, FIG. 11 illustrates an example that two display panels 200a and 200b are disposed on one wiring substrate 260 in a horizontal direction (or left and right) and one display panel 200c is disposed above two display panels 200a and 200b, but the example embodiment is not limited thereto.

Referring to FIG. 11, the display device according to another example embodiment of the present disclosure can include three display panels (200a, 200b, 200c: 200) and one wiring substrate 260 disposed on rear surfaces of the display panels (200a, 200b, 200c: 200).

For example, the display panels (200a, 200b, 200c: 200) can include a first display panel 200a and a second display panel 200b which are sequentially disposed in a horizontal direction. Further, for example, the display panels (200a, 200b, 200c: 200) can further include a third display panel 200c disposed above the first display panel 200a and the second display panel 200b. The first display panel 200a and the second display panel 200b can be lower display panels and the third display panel 200c can be an upper display panel.

For example, the first display panel 200a, the second display panel 200b, and the third display panel 200c can have the same size or different sizes. Further, the first display panel 200a and the second display panel 200b can be disposed at the same height or at different heights.

For example, at the lower side of FIG. 11, the first display panel 200a and the second display panel 200b can be electrically connected to at least one first flexible film and at least one second flexible film through a plurality of first connection lines 281a. Further, at the upper side of FIG. 11, the third display panel 200c can be electrically connected to at least one third flexible film through a plurality of second connection lines 281b.

The first flexible film, the second flexible film, and the third flexible film are disposed on one end and the other end of the wiring substrate 260 to supply a power voltage and a data voltage to the plurality of sub pixels and the circuit of the active areas of the first display panel 200a, the second display panel 200b, and the third display panel 200c through the plurality of first connection lines 281a and the plurality of second connection lines 281b.

For example, the first connection line 281a and the second connection line 281b can be configured by a metal material having a low resistance, low reflectance, and high transmittance.

According to another example embodiment of the present disclosure, the first connection line 281a can extend to rear surfaces of the first display panel 200a and the second display panel 200b so as to overlap parts of the first display panel 200a and the second display panel 200b. The second connection line 281b can extend to the rear surface of the third display panel 200c so as to overlap a part of the third display panel 200c.

The first flexible film, the second flexible film, and the third flexible film can be tape carrier packages (TCP) or chip on films (COF). For example, one edge portion (or an output bonding unit) of the first flexible film can be attached to the plurality of first third pads (or input pads) 283a disposed on the wiring substrate 260. Further, the other edge portion (or an input bonding unit) of the first flexible film can be attached to the first printed circuit board. For example, one edge portion (or an output bonding unit) of the second flexible film can be attached to the plurality of second third pads (or input pads) 283b disposed on the wiring substrate 260. Further, the other edge portion (or an input bonding unit) of the second flexible film can be attached to the second printed circuit board. For example, one edge portion (or an output bonding unit) of the third flexible film can be attached to the plurality of third-third pads (or input pads) 283c disposed on the wiring substrate 260. Further, the other edge portion (or an input bonding unit) of the third flexible film can be attached to the third printed circuit board. For example, the first printed circuit board and the second printed circuit board can be configured by one printed circuit board.

For example, the plurality of first link lines 282a can connect the plurality of first connection lines 281a and the first third pad 283a, individually (or one to one). For example, the plurality of second link lines 282b can connect the plurality of second connection lines 281b and the second third pad 283b, individually (or one to one). For example, the plurality of third link lines 282c can connect the plurality of third connection lines 281c and the third-third pad 283c, individually (or one to one).

As described above, each of the display panels (200a, 200b, 200c: 200) according to another example embodiment of the present disclosure can include first substrates 210a, 210b, 210c, second substrates 250a, 250b, 250c, an element unit, and routing lines 275a, 275b, 275c.

For example, for example, the first display panel 200a can include a first-first substrate 210a, a first second substrate 250a, an element unit, and a first routing line 275a. For example, for example, the second display panel 200b can include a second first substrate 210b, a second-second substrate 250b, an element unit, and a second routing line 275b. Further, for example, the third display panel 200c can include a third first substrate 210c, a third second substrate 250c, an element unit, and a third routing line 275c.

In the meantime, according to still another example embodiment of the present disclosure, the routing line is disposed on a bottom surface of the first substrate so as to cover the top surface of the second substrate. Therefore, the display panel can be attached not only to the top surface of the wiring substrate, but also to the rear surface, which will be described in detail with reference to the drawings.

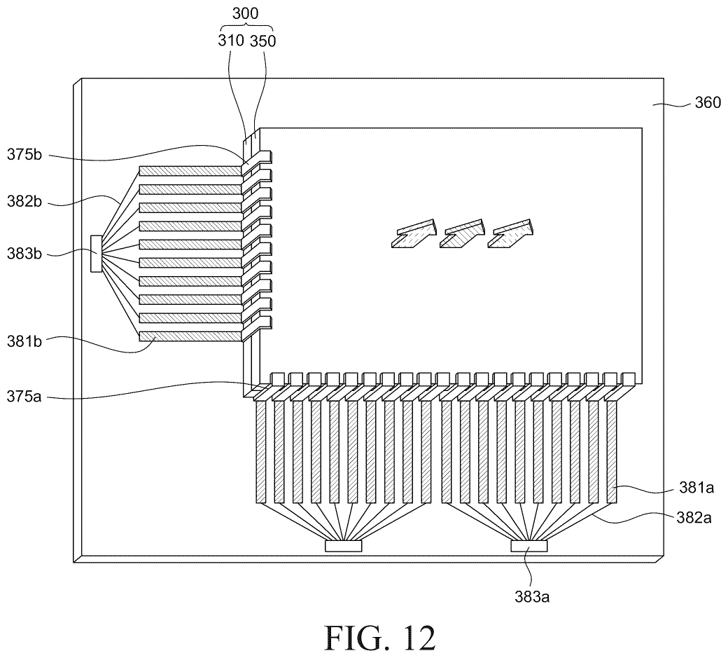

FIG. 12 is a perspective view illustrating a display device according to still another embodiment of the present disclosure.

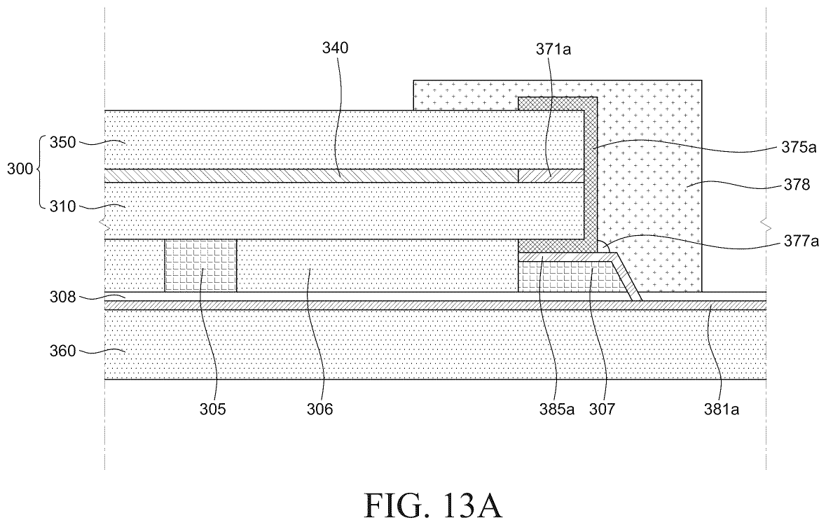

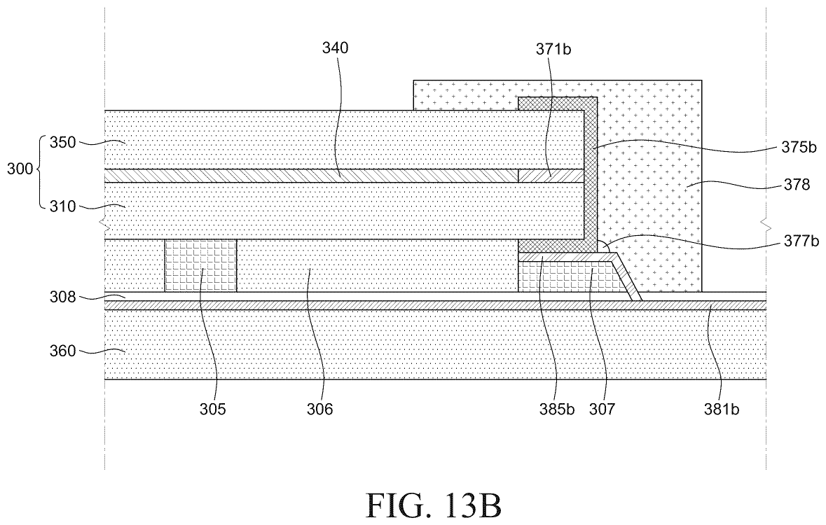

FIGS. 13A and 13B are views illustrating a cross-section of the display device of FIG. 12.

The display device according to still another example embodiment of the present disclosure of FIGS. 12, 13A, and 13B is configured by the substantially same configuration as the display device of the example embodiment of FIGS. 5 to 7 except that routing lines 375a and 375b are disposed on the bottom surface of the first substrate 310 so as to cover the top surface of the second substrate 350 and connection lines 381a and 381b are disposed not only at a lower side of the display panel 300, but also at the left side. Therefore, the same configuration is denoted by the same reference numeral and a description thereof will be omitted or may be briefly provided.

Particularly, FIGS. 12, 13A, and 13B illustrate an example that one display panel 300 is disposed on one wiring substrate 360, but it is not limited thereto. The present disclosure can also be applied to an example that a plurality of display panels 300 is disposed on one wiring substrate 360 like the example embodiment described above.

FIG. 13A illustrates a part of a cross-section taken along one first connection line 381a of the display device of FIG. 12 as an example and FIG. 13B illustrates a part of a cross-section taken along one second connection line 381b of the display device of FIG. 12 as an example.

Referring to FIGS. 12, 13A, and 13B, a display device according to still another example embodiment of the present disclosure can include at least one display panel 300 and one wiring substrate 360 disposed on a rear surface of the display panel 300.

The lower side of FIG. 12 can be defined as a data pad part which is connected to the first flexible film through the first connection line 381a and the left side can be defined as a gate pad part which is connected to the second flexible film through the second connection line 381b, but the present disclosure is not limited thereto.

A first flexible film and a second flexible film are films which supply a signal to the plurality of sub pixels and the circuits of the active area and can be electrically connected to the wiring substrate 360. For example, the first flexible film and the second flexible film are disposed on one end and the other end of the wiring substrate 360 to supply a power voltage, a data voltage (signal), and a gate signal to the plurality of sub pixels and circuits of the active area through the plurality of first connection lines 381a and the second connection line 381b.

For example, the first connection line 381a and the second connection line 381b can be configured by a metal material having a low resistance, low reflectance, and high transmittance. According to still another example embodiment of the present disclosure, the first connection line 381a and the second connection line 381b can extend, respectively, to the rear surface of the display panel 300 so as to overlap a part of the display panel 300, without overlapping each other.

The first connection line 381a can be disposed on the top surface of the wiring substrate 360 in the up and down direction (or a vertical direction) and the second connection line 381b can be disposed on the top surface of the wiring substrate 360 in the left and right direction (or horizontal direction).

An insulating layer 308 can be disposed on the first connection line 381a and the second connection line 381b. The insulating layer 308 can be disposed so as to insulate the first connection line 381a and the second connection line 381b from configurations above the first connection line 381a and the second connection line 381b and for example, can be configured by a single layer of silicon oxide (SiOx) or silicon nitride (SiNx) or a multiple layer thereof.

The first flexible film and the second flexible film can be tape carrier packages (TCP) or chip on films (COF). At this time, for example, one edge portion (or an output bonding unit) of the first flexible film can be attached to the plurality of first to third pads (or input pads) 383a disposed on the wiring substrate 360. Further, the other edge portion (or an input bonding unit) of the first flexible film can be attached to the first printed circuit board. For example, one edge portion (or the output bonding unit) of the second flexible film can be attached to the second third pad (or the input pad) 383b disposed on the wiring substrate 360 and the other edge portion (or the input bonding unit) of the second flexible film can be attached to the second printed circuit board.

For example, the plurality of first link lines 382a can connect the plurality of first connection lines 381a and the first third pad 383a, individually (or one to one). For example, the plurality of second link lines 382b can connect the plurality of second connection lines 381b and the second third pad 383b, individually (or one to one).

As described above, the display panel 300 according to still another example embodiment of the present disclosure can include a first substrate 310, a second substrate 350, an element unit 340, and routing lines 375a and 375b.

For example, a size of the second substrate 350 can be equal to or corresponds to a size of the first substrate 310.

The second substrate 350 can be coupled (or bonded) to the first surface of the first substrate 310 by means of the element unit 340. The second substrate 350 can include a rear surface (or a back surface) which faces the first surface of the first substrate 310 or is coupled to the element unit 340, a front surface which is opposite to the rear surface, and an outside surface between the front surface and the rear surface.

The element unit 340 can be interposed between the first substrate 310 and the second substrate 350. For example, the element unit 340 can be configured by a TFT element layer including a thin film transistor, a light emitting diode layer including a light emitting diode, and an encapsulation layer including an adhesive film, but it is not limited thereto.

The display panel 300 can include pixel driving lines and a plurality of pixels disposed on the first substrate 310. Each of the pixel driving lines can be electrically connected to a plurality of first-first pads 371a disposed on the first edge portion (or a lower side) of the first surface (or a top surface) of the first substrate 310 and/or a plurality of second first pads 371b disposed on the second edge portion (or a left side). For example, the plurality of first-first pads 371a can be divided (or classified) into a plurality of first data pads, a plurality of first pixel driving power pads, and a plurality of first pixel common power pads and the plurality of second first pads 371b can be divided (classified) into a plurality of first gate pads.

The display device according to still another example embodiment of the present disclosure of FIG. 12 applies a top attachment method that the display panel 300 is attached to the top surface of the wiring substrate 360 and pixel driving lines and a plurality of pixels are disposed on the first substrate 310 of the display panel 300 to emit light to the top surface of the wiring substrate 360. However, the present disclosure is not limited thereto.

In the meantime, the wiring substrate 360 can be disposed on the rear surface of the display panel 300 by means of an adhesive layer 306. For example, the second surface (or the rear surface) of the first substrate 310 of the display panel 300 can be coupled to one surface of the adhesive layer 306 and the top surface of the wiring substrate 360 can be coupled to the other surface of the adhesive layer 306. Accordingly, the display panel 300 and the wiring substrate 360 which are bonded (or coupled) to each other by means of the adhesive layer 306 can configure a transparent display device having an island shape.

For example, the display device according to still another example embodiment can include a second pad part PP2 (see FIG. 3) disposed on the wiring substrate 360. The second pad part PP2 can include a plurality of second pads 385a and 385b which is disposed with a constant interval along the first direction (X direction, see FIG. 3) and overlaps the plurality of first pads 371a and 371b of the first pad part PP1 (see FIG. 3). For example, the plurality of second pads 385a and 385b can include a plurality of first second pads 385a which overlaps the plurality of first-first pads 371a, respectively, and a plurality of second-second pads 385b which overlaps the plurality of second first pads 371b, respectively. For example, the plurality of first second pads 385a can be divided (or classified) into a plurality of second data pads, a plurality of second pixel driving power pads, and a plurality of second pixel common power pads and the plurality of second-second pads 385b can be divided (classified) into a plurality of second gate pads. In this case, the gate in panel (GIP) area and the GIP circuit are not necessary.

For example, the first second pad 385a and the second-second pad 385b can apply a double film of Ti/Cu which is applied to the laser soldering process, but is not limited thereto.

The plurality of first routing lines 375a and the plurality of second routing lines 375b can be disposed at the lower side and the left side of the display panel 300 so as to enclose an outside surface of the display panel 300. For example, the plurality of first routing lines 375a and the plurality of second routing lines 375b can be disposed at the lower side and the left side of the display panel 300 so as to cover a part of the top surface of the second substrate 350 in a part of the bottom surface of the first substrate 310, including the outside surface of the display panel 300.

Each first routing line 375a can be electrically connected to the side surface of each first-first pad 371a disposed between the first substrate 310 and the second substrate 350. Each second routing line 375b can be electrically connected to a side surface of each second first pad 371b disposed between the first substrate 310 and the second substrate 350.

A step supplement layer 307 which considers the step by the plurality of first routing lines 375a and the plurality of second routing lines 375b can be disposed at the lower side and the left side of the display panel 300. For example, the step supplement layer 307 can be configured by an organic insulating layer of photo acryl (PAC), but is not limited thereto.

Therefore, the plurality of first second pads 385a and the plurality of second-second pads 385b are disposed on the top surface of the step supplement layer 307 and extend along an inclined side surface of the step supplement layer 307 to be electrically connected to the first connection line 381a and the second connection line 381b. For example, the plurality of first second pads 385a and the plurality of second-second pads 385b can be electrically connected to the first connection line 381a and the second connection line 381b, respectively, through a contact hole formed in the insulating layer 308.

In the meantime, the display device according to still another example embodiment of the present disclosure can further include a support layer 305 which is disposed between the display panel 300 and the wiring substrate 360 to maintain a constant gap between the display panel 300 and the wiring substrate 360. For example, the support layer 305 can be dispersed and disposed in the adhesive layer 306. The support layer 305 can be a column spacer. For example, the support layer 306 can be configured by an organic insulating layer of photo acryl (PAC), but is not limited thereto.

Further, for example, after attaching the display panel 300 to the wiring substrate 360, in order to reinforce the connection of the routing lines 375a and 375b and the second pads 385a and 385b, a first solder paste 377a can be additionally applied between a side surface of the first routing line 375a and the top surface of the first second pad 385a, respectively. Further, a second solder paste 377b can be additionally applied between a side surface of the second routing line 375b and a top surface of the second-second pad 385b, respectively.

Further, for example, a sealant 378 can be applied so as to cover the routing lines 375a and 375b, the second pads 385a and 385b, a part of the top surface of the wiring substrate 360, and a part of the lower side and the left side of the display panel 300, including the solder pastes 377a and 377b. For example, the sealant 378 can be formed of a transparent organic material.

In the meantime, according to still another example embodiment of the present disclosure, a bottom attachment method that the display panel is attached to the rear surface (or a bottom surface) of the wiring substrate and the light is emitted from the rear surface to the top surface of the wiring substrate is also applied. This will be described in detail with reference to drawings.

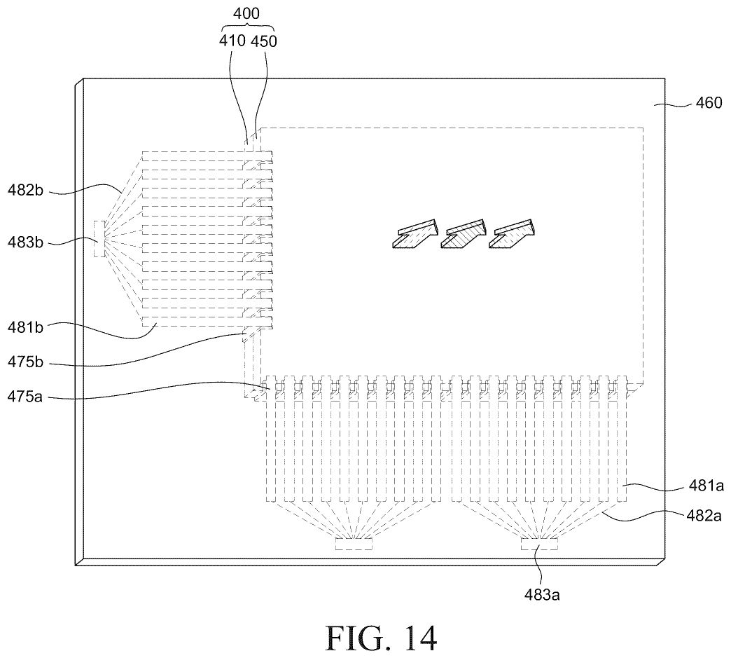

FIG. 14 is a perspective view illustrating a display device according to still another embodiment of the present disclosure.

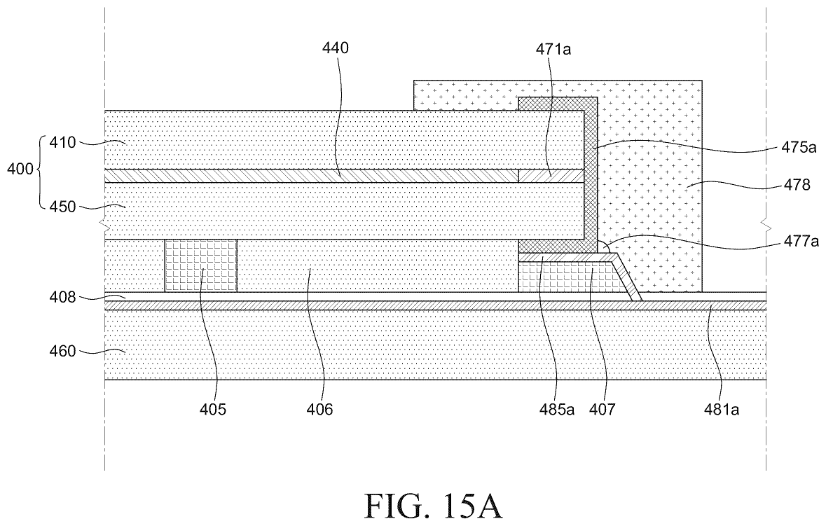

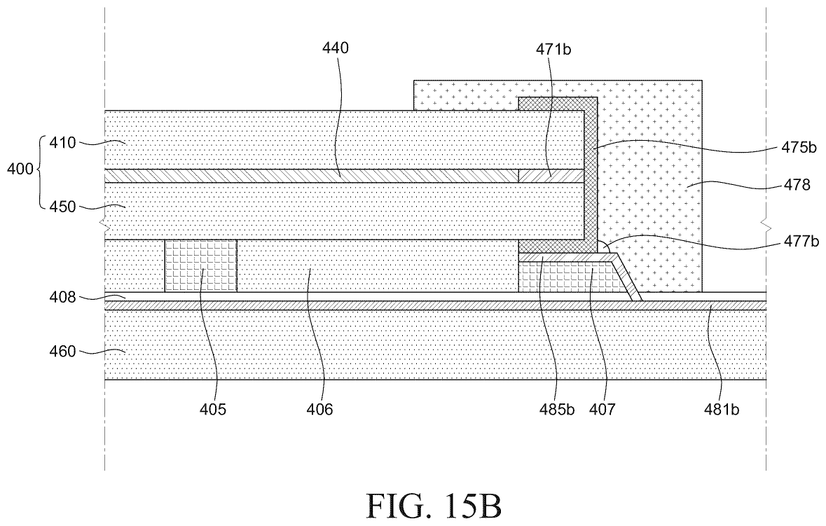

FIGS. 15A and 15B are views illustrating a cross-section of the display device of FIG. 14.

The display device according to still another example embodiment of the present disclosure of FIGS. 14, 15A, and 15B is configured by the substantially same configuration as the display device according to still another example embodiment of FIGS. 12, 13A, and 13B except that a display panel 400 is attached to the rear surface of the wiring substrate 460 and the positions of a first substrate 410 and a second substrate 450 are switched. Therefore, the same configuration is denoted by the same reference numeral and a description thereof will be omitted or may be briefly provided.

Particularly, FIGS. 14, 15A, and 15B illustrate an example that one display panel 400 is disposed on one wiring substrate 460, but it is not limited thereto. The present disclosure is also applied to an example that a plurality of display panels 400 is disposed on one wiring substrate 460 like the example embodiment described above.

FIG. 15A illustrates a part of a cross-section taken along one first connection line 481a of the display device of FIG. 14 as an example and FIG. 15B illustrates a part of a cross-section taken along one second connection line 481b of the display device of FIG. 14 as an example.

Hereinafter, for the convenience of description, a rear surface direction of the wiring substrate 460 is defined as a rear surface (or a bottom surface) of the display panel 400 and a front surface direction of the wiring substrate 460 is defined as a front surface (or a top surface) of the display panel 400.

Referring to FIGS. 14, 15A, and 15B, the display device according to still another example embodiment of the present disclosure can include at least one display panel 400 and one wiring substrate 460 disposed on a top surface of the display panel 400. For example, for example, the display panel 400 can be disposed on the rear surface of the wiring substrate 460 with respect to a watching position of a viewer.

The lower side of FIG. 14 can be defined as a data pad part which is connected to the first flexible film through the first connection line 481a and the left side can be defined as a gate pad part which is connected to the second flexible film through the second connection line 481b, but the present disclosure is not limited thereto.

A first flexible film and a second flexible film are films which supply a signal to the plurality of sub pixels and the circuits of the active area and can be electrically connected to the wiring substrate 460. For example, the first flexible film and the second flexible film are disposed on one end and the other end of the wiring substrate 460 to supply a power voltage, a data voltage (signal), and a gate signal to the plurality of sub pixels and circuits of the active area through the plurality of first connection lines 481a and the second connection line 481b.

For example, the first connection line 481a and the second connection line 481b can be configured by a metal material having a low resistance, low reflectance, and high transmittance. According to still another example embodiment of the present disclosure, the first connection line 481a and the second connection line 481b can extend to the top surface of the display panel 400 so as to overlap a part of the display panel 400, without overlapping each other.

The first connection line 481a can be disposed on the rear surface of the wiring substrate 460 in the up and down direction (or a vertical direction) and the second connection line 481b can be disposed on the rear surface of the wiring substrate 460 in the left and right direction (or horizontal direction).

An insulating layer 408 can be disposed on the first connection line 481a and the second connection line 481b. The insulating layer 408 can be disposed so as to insulate the first connection line 481a and the second connection line 381b from configurations above the first connection line 481a and the second connection line 481b and for example, can be configured by a single layer of silicon oxide (SiOx) or silicon nitride (SiNx) or a multiple layer thereof.

The first flexible film and the second flexible film can be tape carrier packages (TCP) or chip on films (COF). At this time, for example, one edge portion (or an output bonding unit) of the first flexible film can be attached to the plurality of first to third pads (or input pads) 483a disposed on the wiring substrate 460. Further, the other edge portion (or an input bonding unit) of the first flexible film can be attached to the first printed circuit board. For example, one edge portion (or the output bonding unit) of the second flexible film can be attached to the second third pad (or the input pad) 483b disposed on the wiring substrate 460 and the other edge portion (or the input bonding unit) of the second flexible film can be attached to the second printed circuit board.

For example, the plurality of first link lines 482a can connect the plurality of first connection lines 481a and the first third pad 483a, individually (or one to one). For example, the plurality of second link lines 482b can connect the plurality of second connection lines 481b and the second third pad 483b, individually (or one to one).

As described above, the display panel 400 according to still another example embodiment of the present disclosure can include a first substrate 410, a second substrate 450, an element unit 440, and routing lines 475a and 475b.

For example, a size of the second substrate 450 can be equal to or correspond to a size of the first substrate 410.

Further, for example, in the display panel 400 of still another example embodiment of the present disclosure, the first substrate 410 can be disposed on the rear surface (or a back surface) of the second substrate 450 by means of the element unit 440.

The element unit 440 can be interposed between the first substrate 410 and the second substrate 450. For example, the element unit 440 can be configured by a TFT element layer including a thin film transistor, a light emitting diode layer including a light emitting diode, and an encapsulation layer including an adhesive film, but it is not limited thereto.

The display panel 400 can include pixel driving lines and a plurality of pixels disposed on the first substrate 410. Each of the pixel driving lines can be electrically connected to the plurality of first-first pads 471a disposed on the first edge portion (or a lower side) of the first surface (or a top surface) of the first substrate 410 and/or the plurality of second first pads 471b disposed on the second edge portion (or a left side). For example, the plurality of first-first pads 471a can be divided (or classified) into a plurality of first data pads, a plurality of first pixel driving power pads, and a plurality of first pixel common power pads and the plurality of second first pads 471b can be divided (classified) into a plurality of first gate pads.

The display device according to still another example embodiment of the present disclosure of FIG. 14 applies a bottom attachment method that the display panel 400 is attached to the rear surface of the wiring substrate 460 and pixel driving lines and a plurality of pixels are disposed on the first substrate 410 of the display panel 400 to emit light to the top surface of the wiring substrate 460. However, the present disclosure is not limited thereto.

In the meantime, the wiring substrate 460 can be disposed on the rear surface of the display panel 400 by means of an adhesive layer 406. For example, for example, the second surface (or the top surface) of the second substrate 450 of the display panel 400 can be coupled to one surface of the adhesive layer 406 and the rear surface of the wiring substrate 460 can be coupled to the other surface of the adhesive layer 406. Accordingly, the display panel 400 and the wiring substrate 460 which are bonded (or coupled) to each other by means of the adhesive layer 406 can configure a transparent display device having an island shape.

For example, the display device according to still another example embodiment can include a second pad part PP2 (see FIG. 3) disposed on the rear surface of the wiring substrate 460. The second pad part PP2 can include a plurality of second pads 485a and 485b which is disposed with a constant interval along the first direction (X direction, see FIG. 3) and overlaps the plurality of first pads 471a and 471b of the first pad part PP1 (see FIG. 3). For example, the plurality of second pads 485a and 485b can include a plurality of first second pads 485a which overlaps the plurality of first-first pads 471a, respectively, and a plurality of second-second pads 485b which overlaps the plurality of second first pads 471b, respectively. For example, the plurality of first second pads 485a can be divided (or classified) into a plurality of second data pads, a plurality of second pixel driving power pads, and a plurality of second pixel common power pads and the plurality of second-second pads 485b can be divided (classified) into a plurality of second gate pads. In this case, the gate in panel (GIP) area and the GIP circuit are not necessary.

For example, the first second pad 485a and the second-second pad 485b can apply a double film of Ti/Cu which is applied to the laser scolding process, but is not limited thereto.

The plurality of first routing lines 475a and the plurality of second routing lines 475b can be disposed at the lower side and the left side of the display panel 400 so as to enclose an outside surface of the display panel 400. For example, the plurality of first routing lines 475a and the plurality of second routing lines 475b can be disposed at the lower side and the left side of the display panel 400 so as to cover a part of the rear surface of the first substrate 410 in a part of the top surface of the second substrate 450, including the outside surface of the display panel 400.

Each first routing line 475a can be electrically connected to the side surface of each first-first pad 471a disposed between the first substrate 410 and the second substrate 450. Each second routing line 475b can be electrically connected to a side surface of each second first pad 471b disposed between the first substrate 410 and the second substrate 450.

A step supplement layer 407 which considers the step by the plurality of first routing lines 475a and the plurality of second routing lines 775b can be disposed at the lower side and the left side of the display panel 400. For example, the step supplement layer 407 can be configured by an organic insulating layer of photo acryl (PAC), but is not limited thereto.

Therefore, each of the plurality of first second pads 485a and the plurality of second-second pads 485b is disposed on the top surface of the step supplement layer 407 and extend along an inclined side surface of the step supplement layer 407 to be electrically connected to each of the first connection line 481a and the second connection line 481b. For example, the plurality of first second pads 485a and the plurality of second-second pads 485b can be electrically connected to the first connection line 481a and the second connection line 481b, respectively, through a contact hole formed in the insulating layer 408.

In the meantime, the display device according to still another example embodiment of the present disclosure can further include a support layer 405 which is disposed between the display panel 400 and the wiring substrate 460 to maintain a constant gap between the display panel 400 and the wiring substrate 460. For example, the support layer 405 can be dispersed and disposed in the adhesive layer 406. The support layer 405 can be a column spacer. For example, the support layer 406 can be configured by an organic insulating layer of photo acryl (PAC), but is not limited thereto.

Further, for example, after attaching the display panel 400 to the wiring substrate 460, in order to reinforce the connection of the routing lines 475a and 475b and the second pads 485a and 485b, a first solder paste 475a can be additionally applied between a side surface of the first routing line 475a and the top surface of the first second pad 485a, respectively. Further, a second solder paste 477b can be additionally applied between a side surface of the second routing line 475b and a top surface of the second-second pad 485b, respectively.

Further, for example, a sealant 477 can be applied so as to cover the routing lines 475a and 475b, the second pads 485a and 485b, a part of the rear surface of the wiring substrate 460, and a part of the lower side and the left side of the display panel 400, including the solder pastes 477aa and 477b. For example, the sealant 478 can be formed of a transparent organic material.

The example embodiments of the present disclosure can also be described as follows:

According to an aspect of the present disclosure, there is provided a display device. The display device includes at least one transparent display panel, a plurality of routing lines disposed on an outside surface of at least one side of the display panel and a transparent wiring substrate which can be disposed on a rear surface or a top surface of the at least one display panel and can have a plurality of connection lines connected to each of the plurality of routing lines, the plurality of connection lines can extend to the rear surface of the display panel to overlap a part of the display panel.

The display device can further comprise an adhesive layer which can be disposed between the display panel and the wiring substrate to bond the display panel and the wiring substrate and a support layer which can be disposed between the display panel and the wiring substrate to maintain a gap between the display panel and the wiring substrate.

The display panel can include a first substrate, a second substrate which can be opposite to the first substrate and an element unit between the first substrate and the second substrate.

The element unit can include a TFT element layer, a light emitting diode layer, and an encapsulation layer.

The second substrate can have a size smaller than that of the first substrate to expose one side of the first substrate and a plurality of first pads can be disposed at the one side of the exposed first substrate.

The display device can further comprise a plurality of second pads which can be disposed on a top surface or a rear surface of the wiring substrate to overlap the plurality of first pads.

The routing line can be disposed to enclose an outside surface at the one side of the first substrate and each of the plurality of routing lines can be connected to a pixel driving line one to one through the first pad disposed on the first substrate.

Each of the plurality of routing lines can connect each of the plurality of first pads and each of the plurality of second pads one to one.

The display device can further comprise a plurality of third pads which can be disposed on a top surface or rear surface of one side of the wiring substrate.

Each of the plurality of connection lines can connect each of the plurality of second pads and each of the plurality of third pads one to one.

The display device can further comprise a printed circuit board disposed at one side of the wiring substrate and a flexible film which can be electrically connected to the third pad through one edge portion and can be electrically connected to the printed circuit board through the other edge portion.

The at least one display panel can be sequentially disposed in a horizontal direction or sequentially disposed in a vertical direction.

The connection line can be disposed on an entire surface of the wiring substrate with a constant pitch.

The at least one display panel can include at least one lower display panel and at least one upper display panel disposed above the at least one lower display panel.

The connection line can include a lower connection line which can extend to a rear surface of the at least one lower display panel to overlap a part of the at least one lower display panel and an upper connection line which extends to a rear surface of the at least one upper display panel to overlap a part of the at least one upper display panel.

The connection line can include a first connection line which can be disposed in an up and down direction to overlap a part of a lower side of the display panel and a second connection line which can be disposed in a left and right direction to overlap a part of at least one of left and right sides of the display panel.

The routing line can include a first routing line which can be disposed at the lower side of the display panel to cover a part of a top surface of the second substrate from a part of a bottom surface of the first substrate, including an outside surface of the display panel and a second routing line which can be disposed in the at least one of the left and right sides of the display panel to cover the part of the top surface of the second substrate from the part of the bottom surface of the first substrate, including the outside surface of the display panel.

The first routing line can be electrically connected to a side surface of a first-first pad disposed between the first substrate and the second substrate and the second routing line can be electrically connected to a side surface of a second first pad disposed between the first substrate and the second substrate.

The display device can further comprise a step supplement layer which can be disposed between one side of the display panel on which the routing line can be disposed and the wiring substrate, the plurality of second pads can be disposed on a top surface of the step supplement layer and extends along an inclined side surface of the step supplement layer to be electrically connected to the connection line.

The display device can further comprise a solder paste which can be applied between a side surface of the routing line and a top surface of the second pad and a sealant which can include the solder paste to cover the routing line, the second pad, a part of the top surface of the wiring substrate, and a part of a lower side of the display panel.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
at least one transparent display panel;
a plurality of routing lines disposed on an outside surface of at least one side of the at least one transparent display panel; and
a transparent wiring substrate disposed on a rear surface or a top surface of the at least one transparent display panel, and having a plurality of connection lines connected to the plurality of routing lines,
wherein the plurality of connection lines extend to the rear surface of the at least one transparent display panel to overlap a part of the at least one transparent display panel.

2. The display device according to claim 1, further comprising:
an adhesive layer disposed between the at least one transparent display panel and the transparent wiring substrate to bond the at least one transparent display panel and the transparent wiring substrate; and
a support layer disposed between the at least one transparent display panel and the transparent wiring substrate to maintain a gap between the at least one transparent display panel and the transparent wiring substrate.

3. The display device according to claim 1, wherein the at least one transparent display panel includes:
a first substrate;
a second substrate disposed opposite to the first substrate; and
an element unit disposed between the first substrate and the second substrate.

4. The display device according to claim 3, wherein the element unit includes a thin film transistor (TFT) element layer, a light emitting diode layer, and an encapsulation layer.

5. The display device according to claim 3, wherein the second substrate has a size smaller than a size of the first substrate to expose one side of the first substrate, and
wherein a plurality of first pads are disposed at the exposed one side of the first substrate.

6. The display device according to claim 5, further comprising:
a plurality of second pads disposed on a top surface or a rear surface of the transparent wiring substrate to overlap the plurality of first pads.

7. The display device according to claim 6, wherein one of the plurality of routing lines is disposed to enclose an outside surface at the one side of the first substrate, and
wherein each of the plurality of routing lines is connected to a pixel driving line one to one through one of the plurality of first pads disposed on the first substrate.

8. The display device according to claim 6, wherein each of the plurality of routing lines connects one of the plurality of first pads and one of the plurality of second pads one to one.

9. The display device according to claim 6, further comprising:
a plurality of third pads disposed on a top surface or rear surface of one side of the transparent wiring substrate.

10. The display device according to claim 9, wherein each of the plurality of connection lines connects one of the plurality of second pads and one of the plurality of third pads one to one.

11. The display device according to claim 9, further comprising:
a printed circuit board disposed at one side of the transparent wiring substrate; and
a flexible film electrically connected to one of the plurality of third pads through one edge portion and electrically connected to the printed circuit board through another edge portion.

12. The display device according to claim 1, wherein the at least one display panel is sequentially disposed in a horizontal direction or sequentially disposed in a vertical direction.

13. The display device according to claim 1, wherein the connection line is disposed on an entire surface of the transparent wiring substrate with a constant pitch.

14. The display device according to claim 1, wherein the at least one transparent display panel includes:
at least one lower display panel; and
at least one upper display panel disposed on the at least one lower display panel.

15. The display device according to claim 14, wherein one of the plurality of connection lines includes:
a lower connection line extending to a rear surface of the at least one lower display panel to overlap a part of the at least one lower display panel; and
an upper connection line extending to a rear surface of the at least one upper display panel to overlap a part of the at least one upper display panel.

16. The display device according to claim 3, wherein one of the plurality of connection lines includes:
a first connection line disposed in an up and down direction to overlap a part of a lower side of the at least one transparent display panel; and
a second connection line disposed in a left and right direction to overlap a part of at least one of left and right sides of the at least one transparent display panel.

17. The display device according to claim 16, wherein one of the plurality of routing lines includes:
a first routing line disposed at the lower side of the at least one transparent display panel to cover a part of a top surface of the second substrate from a part of a bottom surface of the first substrate, including an outside surface of the at least one transparent display panel; and
a second routing line disposed in the at least one of the left and right sides of the at least one transparent display panel to cover the part of the top surface of the second substrate from the part of the bottom surface of the first substrate, including the outside surface of the at least one transparent display panel.

18. The display device according to claim 17, wherein the first routing line is electrically connected to a side surface of a first-first pad disposed between the first substrate and the second substrate, and the second routing line is electrically connected to a side surface of a second first pad disposed between the first substrate and the second substrate.

19. The display device according to claim 6, further comprising:
a step supplement layer disposed between one side of the at least one transparent display panel on which one of the plurality of routing lines is disposed and the transparent wiring substrate,
wherein the plurality of second pads are disposed on a top surface of the step supplement layer and extending along an inclined side surface of the step supplement layer to be electrically connected to one of the plurality of connection lines.

20. The display device according to claim 6, further comprising:
a solder paste applied between a side surface of one of the plurality of routing lines and a top surface of one of the plurality of second pads; and
a sealant including the solder paste to cover the one routing line, the second pad, a part of the top surface of the transparent wiring substrate, and a part of a lower side of the at least one transparent display panel.
